(19) United States
(12) Patent Application Publication
(10) Pub. No.: US 2016/0251511 A1
(43) Pub. Date: Sep. 1, 2016

(54) RESIN COMPOSITION FOR ENCAPSULATING A SEMICONDUCTOR ELEMENT AND A SEMICONDUCTOR DEVICE

(71) Applicant: Shin-Etsu Chemical Co., Ltd., Tokyo (JP)

(72) Inventors: Shoichi OSADA, Annaka-shi (JP); Ryuhei YOKOTA, Annaka-shi (JP); Hiroki OISHI, Annaka-shi (JP); Tadaharu IKEDA, Annaka-shi (JP)

(73) Assignee: Shin-Etsu Chemical Co., Ltd., Tokyo (JP)

(21) Appl. No.: 15/053,730

(22) Filed: Feb. 25, 2016

(30) Foreign Application Priority Data
Feb. 27, 2015 (JP) 2015-039003

(51) Int. Cl. C08L 63/00; H01L 23/29

(52) U.S. Cl. CPC C08L 63/00; H01L 23/296; C08L 2203/206

(57) ABSTRACT

The purposes of the present invention is to provide a resin composition which provides a cured product which has a high glass transition temperature, a low moisture absorption and a good solder reflow property and small heat decomposition in storage at a high temperature for a long time, and has good moldability and good adhesiveness to a Cu lead frame. Thus, the present invention is to provide a composition comprising (A) an epoxy compound represented by the general formula (1); (B) a copolymer obtained by a hydrosilylation between an alkenyl group-containing epoxy compound and an organopolysiloxane represented by the average compositional formula (2); (C) a phenol compound represented by the general formula (3); (D) an inorganic filler; (E) at least one compound selected from the group consisting of organic phosphines, tetra-substituted phosphonium tetraphenylborates and adducts of phosphines and quinones; and (F) a nitrogen-containing heterocyclic compound represented by the formula (I) or a salt thereof represented by the formula (II). Further, the present invention provides a semiconductor device provided with a cured product obtained by curing the composition.

### CROSS REFERENCE

This application claims the benefits of Japanese Patent application No. 2015-039003 filed on Feb. 27, 2015, the contents of which are hereby incorporated by reference.

### FIELD OF THE INVENTION

The present invention relates to a resin composition for encapsulating a semiconductor element and a semiconductor device provided with a cured product obtained by curing the composition.

### BACKGROUND OF THE INVENTION

Until now, most semiconductor devices such as diodes, transistors, ICs and LSIs are resin encapsulated with resins. Epoxy resins have superior properties such as moldability, adhesiveness, electric properties, mechanical properties and humidity resistance, compared to other thermosetting resins. Therefore, epoxy resin compositions are generally used as resins for encapsulating semiconductor devices. However, recently, in the market of electronic devices, semiconductor devices have been downsized, made lighter and provided with higher performance and more integrated semiconductors. Further, while innovation in the molding technology for semiconductor devices is progressing, further strict requirements are imposed on epoxy resins as materials for encapsulating semiconductors. As a result of the high performance and the high integration, the semiconductor elements generate large heat, so that their junction temperature is so high as 150 to 175 degrees C. Semiconductor devices may have a structure suited to release heat, but the encapsulating resin is required to endure the high temperature. Semiconductor devices for cars or high-voltage applications are often exposed to a high temperature. Therefore, the encapsulating resin needs to have a high glass transition temperature and a high mechanical strength at a high temperature, in addition to the heat resistance.

If a semiconductor device contains moisture, troubles occur with an increasing soldering temperature during mounting, such that a package breaks and an encapsulating material peels from a metal frame, an organic substrate or a semiconductor element surface. Therefore, the encapsulating resin composition needs to have a low moisture absorption and high adhesiveness to a metal frame, an organic substrate and a semiconductor element. However, in general, a resin composition having a high glass transition temperature absorbs a large amount of moisture and a cured product decomposes to reduce its weight in storage at a high temperature.

Japanese Patent Application Laid-Open No. Sho62-212417, Patent Literature 1, describes a copolymer obtained by an addition reaction of an alkenyl group-containing epoxy resin and a hydrosilyl group-containing organopolysiloxane. Further, Patent Literature 1 describes that a material with an excellent crack resistance property for encapsulating a semiconductor element is attained by blending this copolymer to an epoxy resin composition which mainly comprises a curable epoxy resin and a curing agent. However, this resin composition does not have sufficient heat resistance nor low moisture absorption.

Japanese Patent Application Laid-Open No. 2011-252037, Patent Literature 2, describes an epoxy resin composition comprising a phenol novolac resin which has a biphenylene structure in a bridging moiety, an epoxy resin and a curing promoter and a semiconductor encapsulating material comprising the composition. Patent Literature 2 describes that this composition has a high glass transition temperature.

Japanese Patent Application Laid-Open No. 2013-43958, Patent Literature 3, describes an epoxy resin having a chemical structure wherein a biphenylene links a monovalent phenol and a divalent phenol and that a cured product from the resin has a high glass transition temperature, a heat resistance and a flame resistance.

Japanese Patent No. 3388537, Patent Literature 4, describes an epoxy resin composition for encapsulating a semiconductor element. Patent Literature 4 describes that an epoxy resin and a phenol resin curing agent each have a biphenyl structure and a phenol structure which enables the composition gives a cured product having a low moisture absorption, an excellent toughness and excellent crack resistance in a reflow treatment. This is because the resin has the biphenylene structure, so that a distance between cross-linking points is large, and a content of an epoxy group is small and a ratio of a benzene ring is high in the resin.

### PRIOR LITERATURES

### Patent Literatures

[Patent Literature 1] Japanese Patent Application Laid-Open No. Sho62-212417
[Patent Literature 2] Japanese Patent Application Laid-Open No. 2011-252037
[Patent Literature 3] Japanese Patent Application Laid-Open No. 2013-43958
[Patent Literature 4] Japanese Patent No. 3388537
[Patent Literature 5] WO2012/053522

### DISCLOSURE OF THE INVENTION

### Problems to be Solved by the Invention

However, the encapsulating resin compositions described in Patent Literatures 2 and 3 have problems such that their moisture absorptions are not sufficiently low, the compositions decompose with heat at a temperature higher than their glass transition temperatures for a long time to reduce their weights, and cracks and peeling occur in a heat cycle test. The encapsulating resin composition described in Patent Literature 4 has a problem such that its glass transition temperature is low, and the mechanical strength and the electric insulation decrease at a high temperature. The encapsulating resin composition described in Patent Literature 5 has a high glass transition temperature and its weight loss at a high temperature is smaller, but has a problem such that cracks and peeling occur in a heat cycle test. Thus, it was difficult to provide a resin composition having a high glass transition temperature, a high flame retardancy, a low moisture absorption, good storage stability at a high temperature, a good mechanical strength, and good electric insulation.

One of the purposes of the present invention is to provide a resin composition which provides a cured product which has a high glass transition temperature, a low moisture absorption and a good solder reflow property and small heat decomposition in storage at a high temperature for a long time, and has good moldability and good adhesiveness to a Cu lead frame.

### Means to Solve the Problems

To solve the aforesaid problems, the present inventors have made research and found that a composition which comprises an epoxy compound having a biphenylene structure and a phenol compound wherein both of the epoxy compound and the phenol compound have a divalent phenol structure in a specific ratio and further comprises a copolymer obtained by hydrosilylation between an alkenyl group-containing epoxy compound and an organohydrogenpolysiloxane has good moldability and provides a cured product which has a high glass transition temperature, a low moisture absorption property and a good solder reflow property, and low heat decomposition in storage at a high temperature for a long time. Further, the present inventors have found that specific two curing promoters enable the composition to provide a cured product having good adhesiveness to a Cu lead frame, while maintaining the aforesaid effects.

Thus, the present invention is to provide a composition comprising the following components (A) to (F):
(A) an epoxy compound represented by the following general formula (1):

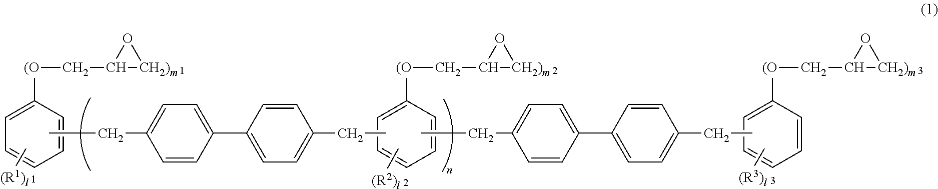

wherein R¹, R² and R³ are, independently of each other, a hydrogen atom or a substituted or unsubstituted, alkyl, aryl or aralkyl group having 1 to 10 carbon atoms, m¹, m² and m³ are, independently of each other, an integer of 1 or 2, provided that a percentage of a total number of m¹, m² and m³ which are integer of 2 is 20 to 100%, relative to a total number of m¹, m² and m³, l¹ is 5 minus m¹, l³ is 5 minus m³, l² is 4 minus m²; and n is an integer of from 0 to 15,
(B) a copolymer obtained by a hydrosilylation between an alkenyl group-containing epoxy compound and an organopolysiloxane represented by the following average compositional formula (2), in an amount of 2 to 20 parts by mass, relative to total 100 parts by mass of components (A), (3) and (C),

$${H}_{a} {R}_{b} {SiO}_{\frac{4 \text{-} ( a + b )}{2}} \qquad ( 2 )$$

wherein R is, independently of each other, a substituted or unsubstituted, monovalent hydrocarbon group having 1 to 10 carbon atoms, a is a positive number of from 0.01 to 1, and b is a positive number of from 1 to 3, provided that a total value of a and b is from 1.01 to less than 4,
(C) a phenol compound represented by the following general formula (3), in an amount of 20 to 50 parts by mass, relative to total 100 parts by mass of components (A), (B) and (C),

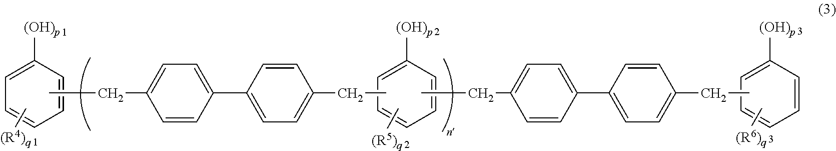

wherein R⁴, R⁵ and R⁶ are, independently of each other, a hydrogen atom or a substituted or unsubstituted, alkyl, aryl or aralkyl group having 1 to 10 carbon atoms, p¹, p² and p³ are, independently of each other, an integer of 1 or 2, provided that a percentage of a total number of p¹, p² and p³ which are an integer of 2 is 20 to 100%, relative to a total number of p¹, p² and p³, q¹ is 5 minus p¹, q³ is 5 minus p³, q² is 4 minus p²; and n′ is an integer of from 0 to 15,
(D) an inorganic filler in an amount of 150 to 1500 parts by mass, relative to total 100 parts by mass of components (A), (B) and (C),
(E) at least one compound selected from the group consisting of organic phosphines, tetra-substituted phosphonium tetraphenylborates and adducts of phosphines and quinones, in an amount of 0.1 to 5 parts by mass, relative to total 100 parts by mass of components (A), (B) and (C), and
(F) at least one selected from compounds represented by the following formula (I) and salts represented by the following formula (II), in an amount of 0.1 to 5 parts by mass, relative to total 100 parts by mass of components (A), (B) and (C),

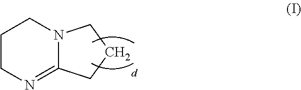

wherein d is an integer of from 1 to 3,

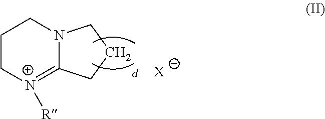

wherein R″ is a hydrogen atom, an aliphatic hydrocarbon group having 1 to 6 carbon atoms or an aromatic hydrocarbon group having 6 to 10 carbon atoms, d is an integer of from 1 to 3, and X is an anion selected from the group consisting of a tetraphenylborate ion, a phenol ion, a phenol resin ion, a toluene sulphonate ion, a halide ion and a carboxylate ion having 1 to 10 carbon atoms.

Further, the present invention provides a semiconductor device provided with a cured product obtained by curing the composition.

### Effects of the Invention

The present composition provides a cured product having a high glass transition temperature and good heat resistance. The cured product shows less heat decomposition, when stored at a high temperature for a long time. The cured product has a low moisture absorption, a good solder reflow property, and good adhesiveness to a Cu lead frame. Therefore, the present composition is suitable for encapsulating a surface mounting type of semiconductor devices.

### BEST MODE OF THE INVENTION

The present invention will be described below in detail.

Component (A) is an epoxy compound represented by the following general formula (1):

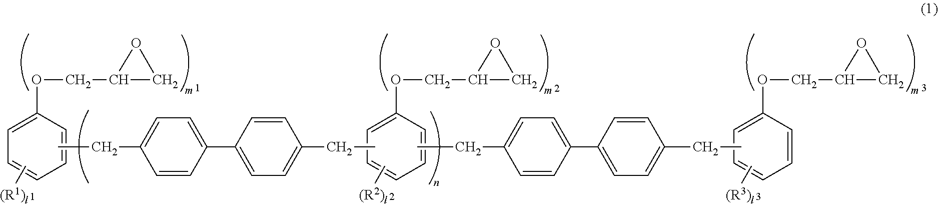

wherein R¹, R² and R³ are, independently of each other, a hydrogen atom or a substituted or unsubstituted, alkyl, aryl or aralkyl group having 1 to 10 carbon atoms, preferably 1 to 6 carbon atoms, m¹, m² and m³ are, independently of each other, an integer of 1 or 2, provided that a percentage of a total number of m¹, m² and m³ which are integer of 2 is 20 to 100%, relative to a total number of m¹, m² and m³, l¹ is 5 minus m¹, l³ is 5 minus m³, l² is 4 minus m²; and n is an integer of from 0 to 15.

The epoxy compound (A) is obtained by epoxidation of a phenol compound in which a monovalent phenol structure and a divalent phenol structure are linked by a biphenylene structure wherein the amount of the monovalent phenol and the amount of the divalent phenol are in the specific ratio. The epoxy compound has the divalent phenol structure in such an amount that a total number of m¹, m² and m³ which are integer of 2 is 20 to 100%, preferably 30 to 100%, relative to a total number of m¹, m² and m³. Here, the percentage of the total number of m¹, m² and m³ which are integer of 2 means the percentage of the number of the divalent phenol structure. When the percentage of the divalent phenol structure is in the aforesaid range, a cured product from the composition has a high glass transition temperature, good storage stability at a high temperature and a low moisture absorption.

The present inventors have found that on account of the requisite that the aforesaid epoxy compound and the phenol compound described below have the divalent phenol structure in the specific amounts, the composition provides a cured product which has the higher glass transition temperature, the superior heat resistance and the lower moisture absorption and decomposes less in storage at a high temperature, compared to a composition comprising an epoxy compound known for the good effect of increasing a glass transition temperature, such as ortho-cresol novolac epoxy resins, triphenol methane epoxy resins, naphthalene epoxy resins and dicyclopentadiene epoxy resins.

R¹, R² and R³ are, independently of each other, a hydrogen atom; an alkyl group such as methyl, ethyl, propyl, isopropyl, butyl, isobutyl, tert-butyl, pentyl, neopentyl, hexyl, octyl, nonyl and decyl groups; an aryl group such as phenyl, tolyl, xylyl and naphthyl groups; or an aralkyl group such as benzyl, phenyl ethyl and phenyl propyl groups; or those groups where a part or the whole of their hydrogen atoms are replaced with a halogen atom(s), such as fluorine, bromine and chlorine atoms, or with a cyano group. Among these, a hydrogen atom, a methyl group, an ethyl group and a phenyl group are preferred.

The present composition may further comprise, in addition to the aforesaid epoxy compound, an epoxy compound in which all of l¹, m² and m³ are an integer of 1. The present composition may comprises other epoxy compounds, such as phenol aralkyl epoxy resins, biphenyl epoxy resins, bis-A epoxy resins, bis-F epoxy resins, naphthalene epoxy resins, ortho-cresol novolac epoxy resins, triphenol alkane epoxy resins and dicyclopentadiene epoxy resins. The amount of these epoxy compounds may be 50% by mass or less, preferably 30% by mass or less, relative to the total mass of these epoxy compounds and the compound represented by the aforesaid formula (1).

Component (B) is a copolymer obtained by a hydrosilylation between an alkenyl group-containing epoxy compound and a hydrogenorganopolysiloxane represented by the following average compositional formula (2). On account of the copolymer, the present composition has the good heat resistance and the low moisture absorption.

$${H}_{a} {R}_{b} {SiO}_{\frac{4 \text{-} ( a + b )}{2}} \qquad ( 2 )$$

wherein R is, independently of each other, a substituted or unsubstituted, monovalent hydrocarbon group having 1 to 10 carbon atoms, preferably 1 to 6 carbon atoms, a is a positive number of from 0.01 to 1, and b is a positive number of from 1 to 3, provided that a total of a and b is from 1.01 to less than 4.

The alkenyl group containing epoxy compound is prepared, for instance, by epoxidation of an alkenyl group-containing phenol resin with epichlorohydrin or by a reaction of a part of a conventional epoxy compound with 2-allylphenol. The alkenyl group containing epoxy compound may be a compound having a moiety represented by the following average compositional formula (4) or (5):

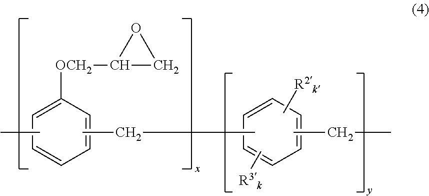

wherein R^{2′} is an alkenyl group-containing monovalent aliphatic hydrocarbon group which has 3 to 15 carbon atoms, preferably 3 to 5 carbon atoms, R^{3′} is a glycidyloxy group or a group represented by —OCH₂CH(OH)CH₂OR′, wherein R′ is an alkenyl group-containing monovalent hydrocarbon group which has 3 to 10 carbon atoms, preferably 3 to 5 carbon atoms, k is 1, k′ is 0 or 1, x is a positive number of 1 to 30, and y is a positive number of 1 to 3;

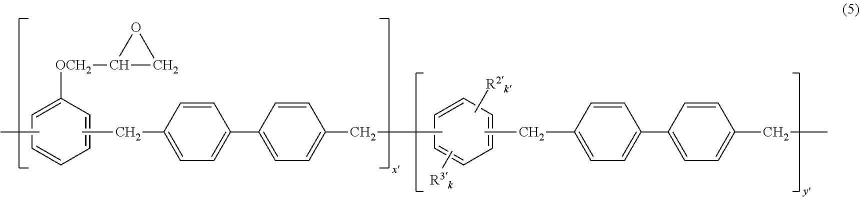

wherein R^{2′}, R^{3′}, k and k′ are as defined above, x′ is a positive number of 1 to 30, and y′ is a positive number of 1 to 3.

Examples of the epoxy compound having the moiety represented by the average compositional formula (4) or (5) include compounds having a moiety represented by the following average compositional formulas.

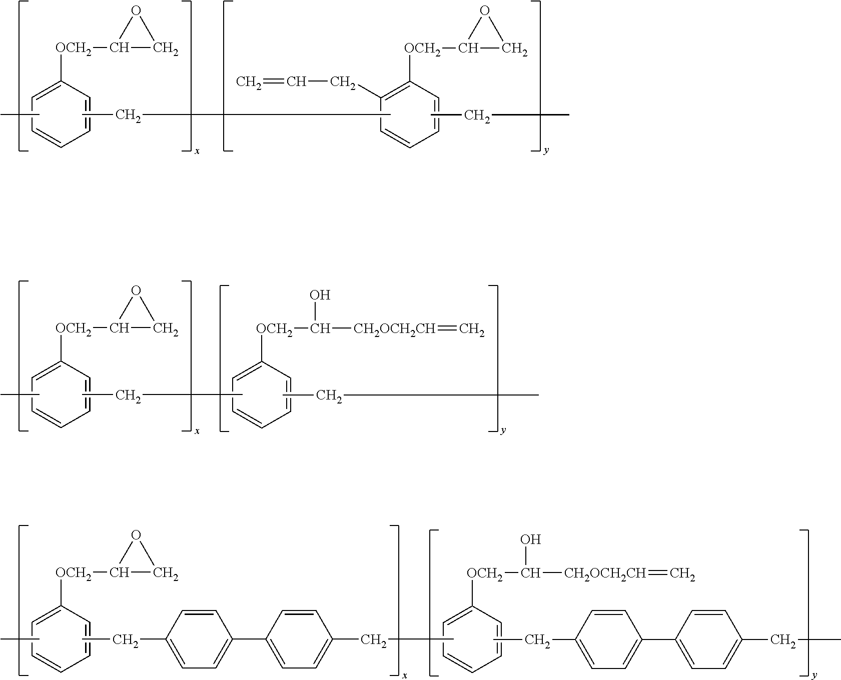

wherein x is a positive number of larger than 1 to less than 10, and y is a positive number of larger than 1 to less than 3.

The organohydrogenpolysiloxane represented by the aforesaid average compositional formula (2) has at least one SiH group. Examples of R include alkyl groups such as methyl, ethyl, propyl, isopropyl, butyl, isobutyl, tert-butyl, pentyl, neopentyl, hexyl, octyl, nonyl and decyl groups; alkenyl groups such as vinyl, allyl, propenyl, isopropenyl, butenyl, hexenyl, cyclohexenyl and octenyl groups; aryl groups such as phenyl, tolyl, xylyl and naphthyl groups; aralkyl groups such as benzyl, phenylethyl and phenylpropyl groups; and those groups where a part or the whole of their hydrogen atoms are replaced with a halogen atom(s), such as fluorine, bromine and chlorine atoms, or with a cyano group, e.g. halogen-substituted alkyl groups, for instance, chloromethyl, chloropropyl, bromoethyl and trifluoropropyl groups, and a cyanoethyl group. Among these, a methyl group, an ethyl group and a phenyl group are preferred.

The organohydrogenpolysiloxane may be linear, cyclic or branched. For instance, the organohydrogenpolysiloxane may be such represented by the following formula (a), (b) or (c).

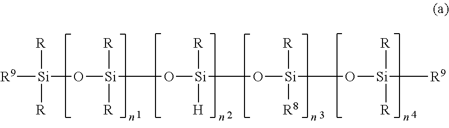

In the formula (a), R is, independently of each other, a substituted or unsubstituted, monovalent hydrocarbon group having 1 to 10, preferably 1 to 6 carbon atoms, R⁹ is a hydrogen atom or a group as defined for R, and R⁸ is a group represented by the following formula. n¹ is an integer of from 5 to 200, n² is an integer of from 0 to 2, n³ is an integer of from 0 to 10, and n⁴ is 1 or 0.

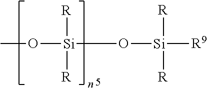

wherein R and R⁹ are as defined above, n⁵ is an integer of from 1 to 10, provided that the compound represented by the formula (a) has at least one hydrogen atom bonded to a silicon atom. The parenthesized siloxane units may bond randomly or form a block unit(s).

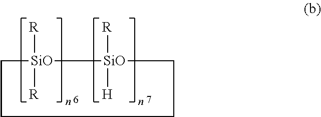

In the formula (b), R is as defined above, n⁶ is an integer of from 1 to 10, and n⁷ is 1 or 2. An order of the parenthesized siloxane units is not limited.

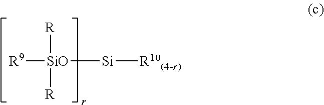

In the formula (c), R and R⁹ are as defined above, r is an integer of from 0 to 3, and R¹⁰ is a hydrogen atom or a monovalent hydrocarbon group which has 1 to 10 carbon atoms and may have an oxygen atom, wherein the compound represented by the formula (c) has at least one hydrogen atom bonded to a silicon atom.

Preferred examples of the aforesaid hydrogenorganopolysiloxane are methylpolysiloxanes having hydrogen atoms at the both terminals and methylphenylpolysiloxanes having hydrogen atoms at the both terminals.

For instance, the following compounds are preferred.

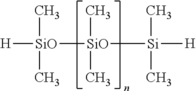

wherein n is an integer of from 20 to 100.

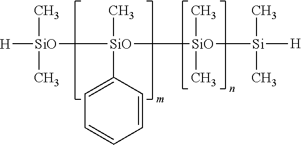

wherein m is an integer of from 1 to 10, and n is an integer of from 10 to 100.

Component (B) is the copolymer obtained by a hydrosilylation between the aforesaid alkenyl group-containing epoxy compound and the aforesaid hydrogenorganopolysiloxane. The hydrosilylation may be conducted in any known manner. For instance, the copolymer is obtained by reacting these compounds with heat in the presence of a platinum containing catalyst such as a chloro platinic acid. In particular, the hydrosilylation may be conducted in an inactive solvent such as benzene, toluene and methylisobutylketone at 60 to 120 degrees C. A ratio of the siloxane to the epoxy compound is preferably such that the number of the SiH group in the siloxane per alkenyl group in the epoxy compound is 1.0 or more, further preferably 1.5 to 5.0.

The amount of component (B) in the composition is 2 to 20 parts by mass, preferably 2 to 8 parts by mass, relative to total 100 parts by mass of components (A), (B) and (C).

Component (C) is the phenol compound represented by the following general formula (3):

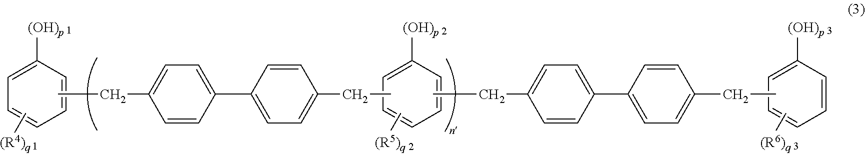

wherein R⁴, R⁵ and R⁶ are, independently of each other, a hydrogen atom or a substituted or unsubstituted, alkyl, aryl or aralkyl group having 1 to 10 carbon atoms, preferably 1 to 6 carbon atoms, p¹, p² and p³ are, independently of each other, an integer of 1 or 2, provided that a percentage of a total number of p¹, p² and p³ which are an integer of 2 is 20 to 100%, preferably 30 to 100%, preferably relative to a total number of p¹, p² and p³, q¹ is 5 minus p¹, q³ is 5 minus p³, q² is 4 minus p²; and n′ is an integer of from 0 to 15.

The compound represented by the formula (3) can be a precursor for preparing the epoxy compound (A). As described above, on account of the requisite that component (C) has a divalent phenol structure in the specific amount, the present composition provides a cured product having a high glass transition temperature, a good heat resistance and a low moisture absorption.

R⁴, R⁵ and R⁶ are, independently of each other, a hydrogen atom; an alkyl group such as methyl, ethyl, propyl, isopropyl, butyl, isobutyl, tert-butyl, pentyl, neopentyl, hexyl, octyl, nonyl and decyl groups; an aryl group such as phenyl, tolyl, xylyl and naphthyl groups; an aralkyl group such as benzyl, phenyl ethyl and phenyl propyl; or those groups where a part or the whole of their hydrogen atoms are replaced with a halogen atom(s), such as fluorine, bromine and chlorine atoms, or with a cyano group. Among these, a hydrogen atom, a methyl group, an ethyl group and a phenyl group are preferred.

The present composition may further comprise, in addition to the aforesaid phenol compound, a phenol compound in which all of p¹, p² and p³ are an integer of 1. The present composition may comprise other phenol compounds such as phenol novolac resins, naphthalene ring-containing phenol resins, aralkyl phenol resins, triphenol alkane phenol resins, biphenyl phenol resins, alicyclic phenol resins, heterocyclic phenol resins, and bisphenol phenol resins such as bisphenol-A or bisphenol-F resins. The amount of these phenol compounds may be 50% by mass or less, preferably 30% by mass or less, relative to a total mass of these phenol compounds and the compound represented by the aforesaid formula (3).

The amount of component (C) in the composition is 20 to 50 parts by mass, preferably 30 to 45 parts by mass, relative to total 100 parts by mass of components (A), (B) and (C).

Component (D) is an inorganic filler. Examples of the inorganic filler include silica such as fumed silica, crystalline silica and cristobalite, alumina, silicon nitride, aluminum nitride, boron nitride, titanium oxide, glass fiber, magnesium oxide and zinc oxide. An average particle size and a shape of the filler are not limited and may be decided, depending on applications. Generally, the average particle diameter is 1 to 50 μm, particularly 4 to 20 μm. The average particle diameter is determined with a laser diffraction particle size analyzer available, for instance, from CILAS.

The inorganic filler preferably contains, per 5 g of the filler, 10 ppm or less of chloride ions and 10 ppm or less of sodium ions as impurities extracted from the filler in the conditions of 50 g of water, 120 degrees C. and 2.1 atms. Further preferably, the amount of chloride ions is 5 ppm or less and the amount of sodium ions is 5 ppm or less. If the amount is more than 10 ppm, moisture resistance of a semiconductor device encapsulated with a cured product of the composition may be worse.

The amount of the inorganic filler is 150 to 1500 parts by mass, preferably 250 to 1200 parts by mass, relative to the total 100 parts by mass of components (A), (B) and (C). In particular, the amount is 60 to 94 mass %, preferably 70 to 92 mass %, further preferably 75 to 90 mass %, relative to a total mass of the composition.

The inorganic filler may be surface-treated with a coupling agent such as a silane coupling agent and a titanate coupling agent in advance. The silane coupling agent is preferably epoxy silanes such as γ-glycidoxypropyltrimethoxysilane, γ-glycidoxypropylmethyldiethoxysilane and β-(3,4-epoxycyclohexyl)ethyltrimethoxysilane; amino silanes such as N-β(aminoethyl)-β-aminopropyltrimethoxysilane, a reactant of imidazol and γ-glycidoxypropyltrimethoxysilane, γ-aminopropyltriethoxysilane and N-phenyl-β-aminopropyltrimethoxysilane; and mercapto silane such as γ-mercapto silane and γ-episulfideoxy propyl trimethoxy silane. The surface treatment may be conducted in any conventional manner. An amount of the coupling agent is not limited.

Another characteristic of the present invention is in that the present composition comprises the combination of (E) phosphine compound and (F) nitrogen-containing heterocyclic compound and/or salts thereof. The phosphine compound (E) is at least one selected from the group consisting of organic phosphines, tetra-substituted phosphonium tetraphenylborates and adducts of phosphines and quinones. Component (F) is at least one selected from the compounds represented by the following formula (I) and the salts thereof represented by the following formula (II).

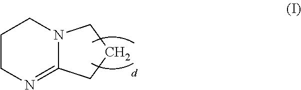

wherein d is an integer of from 1 to 3.

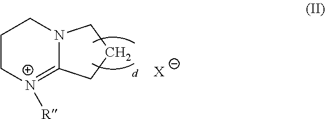

wherein R″ is a hydrogen atom, an aliphatic hydrocarbon group having 1 to 6 carbon atoms or an aromatic hydrocarbon group having 6 to 10 carbon atoms, d is an integer of from 1 to 3, and X is an anion selected from the group consisting of a tetraphenylborate ion, a phenol ion, a phenol resin ion, a toluene sulphonate ion, a halide ion and a carboxylate ion having 1 to 10 carbon atoms.

The composition comprising components (A) to (D) has good moldability and provides a cured product which has a high glass transition temperature, a low moisture absorption and a good solder reflow property, decomposes less with heat in storage at a high temperature for a long time. Another characteristic of the present invention is in that the present composition comprises the combination of components (E) and (F) in addition to compositions (A) to (D). The two components enable the composition to provide a cured product having good adhesiveness to a Cu lead frame, while maintaining the aforesaid effects. If the composition comprises components (A) through (E), but does not comprise component (F), a cured product has less adhesiveness to a Cu lead frame and a worse solder reflow resistance. If the composition comprises components (A) through (D) and (F), but does not comprise component (E), a cured product has a lower glass transition temperature and worse heat resistance. Components (E) and (F) will be described below in detail.

Component (E) is a phosphine compound such as organic phosphines, tetra-substituted phosphonium tetraphenylborates and adducts of phosphines and quinones. These compounds may be any ones known as a curing promoter and may be used singly or in a combination with two or more of them. Examples of the organic phosphine include triphenylphosphine, tributylphosphine, tritolylphosphine, trixylylphosphine and tris(4-methoxyphenyl)phosphine. A complex of the organic phosphine with an organic borane may be used, such as triphenylphosphine triphenylborane. Examples of the tetra-substituted phosphonium tetraphenylborates include tetraphenylphosphine tetraphenylborane, tetraphenylphosphine-tetra-p-tolylborane and tetratolyphosphine tetraphenylborane. An example of the adduct of phosphines and quinones is an adduct of triphenylphosphine and benzoquinone. These are commercially available such as TPP (trademark, triphenylphosphine), ex Hokko chemical industry Co., Ltd. and TPP-K (trademark, tetraphenylphosphine-tetraphenylborane), ex Hokko chemical industry Co., Ltd.

Component (F) is a nitrogen-containing heterocyclic compound represented by the aforesaid formula (I) or a salt thereof represented by the formula (II). The compound may be used singly or in combination with two or more of them. In the aforesaid formula (I), d is an integer of from 1 to 3, preferably 1 or 3. In the aforesaid formula (II), R″ is a hydrogen atom, an aliphatic hydrocarbon group having 1 to 6 carbon atoms or an aromatic hydrocarbon group having 6 to 10 carbon atoms. Examples of the aliphatic hydrocarbon group include alkyl groups such as methyl, ethyl, propyl, isopropyl, butyl, isobutyl, tert-butyl, pentyl and hexyl; and cycloalkyl groups such as cyclopentyl and cyclohexyl groups. Examples of the aromatic hydrocarbon groups include aryl groups such as phenyl and tolyl groups; and aralkyl groups such as benzyl, phenyl ethyl and phenyl propyl groups, preferably a benzyl group. In particular, R″ is a hydrogen atom or a benzyl group. In the aforesaid formula (II), d is an integer of from 1 to 3, preferably or 3. X is an anion selected from the group consisting of a tetraphenylborate ion, a phenol ion, a phenol resin ion, a toluene sulphonate ion, a halide ion and a carboxylate ion having 1 to 10 carbon atoms. An example of the phenol resin ion is a phenol novolac resin ion. An example of the toluene sulphonate ion is a p-toluene sulphonate ion. Examples of the halide ion include a chloride ion and bromide ion. Examples of the carboxylate ion include an octylate ion, a formate ion, an orthophthalate ion and a trimellitate ion. Among these, X is preferably selected from the tetraphenylborate ion, the phenol resin ion and the carboxylate ion having 1 to 10 carbon atoms, in particular, the tetraphenylborate ion and the phenol resin ion.

Examples of the compound represented by the formula (I) include 1,8-diazabicyclo[5.4.0]-undecene-7 (DBU) and 1,5-diazabicyclo[4.3.0]non-ene-5 (DBN). Examples of the compound represented by the formula (II) include a phenol resin salt of 1,8-diazabicyclo[5.4.0]-undecene-7 (DBU), a phenol salt of 1,8-diazabicyclo[5.4.0]-undecene-7 (DBU), a trimellitic acid salt of 1,8-diazabicyclo[5.4.0]-undecene-7 (DBU), p-toluene sulphonate of 1,8-diazabicyclo[5.4.0]-undecene-7 (DBU), 8-benzyl-1,8-diazabicyclo[5,4,0]-undecenium-7 chloride, tetraphenylborate of 8-benzyl-1,8-diazabicyclo[5,4,0]-undecene-7, a phenol resin salt of 1,5-diazabicyclo[4.3.0]non-ene-5 (DBN), and tetraphenylborate of 5-benzyl-1,5-diazabicyclo[4.3.0]non-ene-5. These are commercially available, such as U-CAT (trademark) and U-CAT (trademark) SA series, ex San-Apro Ltd. For instance, U-CAT SA851, U-CAT 5002, U-CAT SA 102, U-CAT SA 1 and U-CAT SA 506 are named.

The amount of each of components (E) and (F) is 0.1 to 5 parts by mass, preferably 0.3 to 1.8 parts by mass, particularly 0.5 to 1.5 parts by mass, relative to total 100 parts by mass of components (A) to (C). Component (E) may be mixed with a phenol curing agent and/or silica in advance.

The present composition may further comprise, if needed, additives such as releasing agents, flame retardants, ion trapping agents, antioxidants and adhesiveness-imparting agents.

Any known releasing agent may be used, such as, for instance, carnauba wax, rice bran wax, polyethylene, oxidized polyethylene, montanic acid, wax such as esters of montanic acid with saturated alcohol, 2-(2-hydroxy ethyl amino)ethanol, ethylene glycol or glycerin; stearic acid, stearate esters, stearic acid amide, ethylene bis(stearic acid amide), copolymers of ethylene and vinyl acetate. These compounds may be used singly or in combination with two or more of them. The amount of the releasing agent is 0.5 to 5 parts by mass, preferably 1 to 3 parts by mass, relative to total 100 parts by mass of components (A), (B) and (C).

Any known flame retardant may be used, such as, for instance, a phosphazene compound, a silicone compound, talc treated with zinc molybdate, zinc oxide treated with zinc molybdate, aluminum hydroxide, magnesium hydroxide, molybdenum oxide and antimony trioxide. These compounds may be used singly or in combination with two or more of them. The amount of the flame retardant is 2 to 20 parts by mass, preferably 3 to 10 parts by mass, relative to the total 100 parts by mass of components (A), (B) and (C).

Any known ion trapping agent may be used, such as, for instance, hydrotalcites, bismuth hydroxide and rare earth oxide. These compounds may be used singly or in combination with two or more of them. The amount of the ion trapping agent is 0.5 to 10 parts by mass, preferably 1.5 to 5 parts by mass, relative to total 100 parts by mass of components (A), (B) and (C).

Any known adhesiveness-imparting agents may be used, such as, for instance, aforesaid coupling agent. These coupling agents may be used singly or in combination with two or more of them. The amount of the adhesiveness-imparting agent is 0.2 to 5 parts by mass, preferably 0.5 to 3 parts by mass, relative to total 100 parts by mass of components (A), (B) and (C).

The present composition may be prepared in any known manner. For instance, components (A) to (F) and the optional components are homogeneously mixed in a predetermined ratio with a mixer, melt kneaded with hot rolls, a kneader or an extruder, cooled to be solid and, then, crushed into a proper size to obtain the composition. The composition obtained is used as a molding material.

The present composition is suitable as a resin for encapsulating semiconductor devices, such as those of a transistor type, module type, DIP type, SO type, flatpack type, or ball grid array type. The manner of encapsulating a semiconductor device with the present composition is not limited to any particular one and may be a conventional manner of molding, such as transfer molding, injection molding and casting method. In particular, transfer molding is preferable.

The conditions for molding and curing the present composition are not limited to any particular one. A temperature of 160 to 190 degrees C. and a period of 45 to 180 seconds are preferred. Further, preferably post curing is conducted at 170 to 250 degrees C. for 2 to 16 hours.

The present resin composition provides a cured product which decomposes less with heat in storage at a high temperature, particularly 200 to 250 degrees C., for a long time, so that a weight loss is small. Therefore, reliability at a high temperature for a long time is excellent. Further, the cured product has good adhesiveness to a copper lead frame or a silver-plated surface, and a high insulating property. The semiconductor device encapsulated with the cured product of the present composition has a good humidity resistance and a good solder reflow resistance. The present composition may be molded with the same equipment and the same molding conditions as those for conventional epoxy resin compositions used as transfer molding materials, with good productivity.

### Examples

The present invention will be explained below in further detail with reference to a series of the Examples and the Comparative Examples, though the present invention is in no way limited by these Examples.

In the following description, the percentage of the number of the monovalent phenol is the percentage of the total number of m¹, m² and m³ which are integer of 1, relative to a total number of m¹, m² and m³, and the percentage of the number of the divalent phenol is the percentage of the total number of m¹, m² and m³ which are integer of 2, relative to a total number of m¹, m² and m³.

### [Component A]

### Epoxy Compound 1

Epoxy compound represented by the following formula (6): NC-3500, ex Nippon Kayaku Co., Ltd.

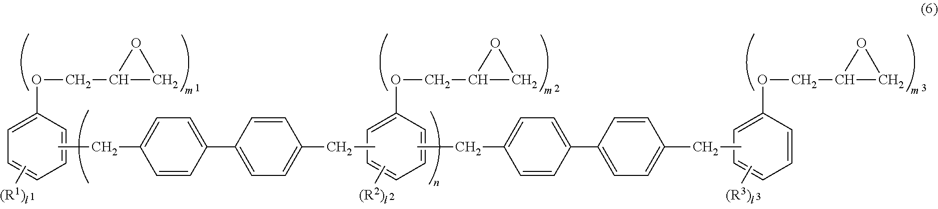

wherein R¹, R² and R³ are a hydrogen atom, the percentage of the number of the monovalent phenol is 36% and the percentage of the number of the divalent phenol is 64%, relative to the total number of the monovalent and divalent phenol groups, an average of n is 1.4 and an epoxy equivalent is 208.

### Epoxy Compound 2

In a glass reaction vessel equipped with a stirrer, a condenser and a nitrogen gas introduction tube, added were 55.0 g (0.33 mol) of a phenol resin in which the percentage of the number of the monovalent phenol was 71% and the percentage of the number of the divalent phenol was 29%, relative to the total number of the monovalent and divalent phenol groups (SH-005-04, ex Meiwa Plastic Industries Ltd., mentioned below), 365.6 g (4.0 mols) of epichlorohydrin and 50 g of methanol. These were dissolved homogeneously. 13.7 Grams (0.3 mol) of 96% sodium hydroxide which was solid was portionwise added to the vessel at 50 degrees C. over 90 minutes. Then, the mixture was allowed to react at 50 degrees C. for 2 hours and, then, at 70 degrees C. for 2 hours. After the reaction, the excess epichlorohydrin was removed under a reduced pressure.

In the vessel, 85 g of methylisobutylketone was added to dissolve the reaction product obtained in the aforesaid step. 5.3 Grams (0.03 mol) of an aqueous 25% sodium hydroxide solution was added to the vessel and allowed to react at 70 degrees C. for 1 hour. After the reaction, the mixture was washed with water seven times, so that the aqueous phase was neutral. Methylisobutylketone was distilled off under heating and reduced pressure to obtain 75 g of epoxy compound 2 which was represented by the aforesaid formula (6) wherein R² and R³ were H, the average of n was 1.3. An epoxy equivalent of epoxy compound 2 obtained was 224.

### Epoxy Compound 3

220 Grams (2.0 mol) of resorcinol was dissolved in 150 g of water in a glass reaction vessel equipped with a stirrer, a condenser and a nitrogen gas introduction tube. 125.5 Grams (0.5 mol) of 4,4′-di(chloromethyl) biphenyl were added to the vessel and reacted at 100 degrees C. for 3 hours. The mixture was heated to 160 degrees C. and all of 4,4′-di(chloromethyl) biphenyl was reacted. During the reaction, HCl generated in the reaction and water were distilled off. After reaction, unreacted resorcinol was removed by distillation under a reduced pressure to obtain 180 g of a phenol resin in which the percentage of the number of the monovalent phenol was 0% and the percentage of the number of the divalent phenol was 100%, relative to the total number of the monovalent and divalent phenol groups. A hydroxyl equivalent of the phenol resin was 115 g/eq.

Subsequently, in a glass reaction vessel, added were 50.0 g (0.41 mol) of the phenol resin obtained in the aforesaid reaction, 451.2 g (4.9 mols) of epichlorohydrin and 50 g of methanol. These were dissolved homogeneously. 16.9 Grams (0.4 mol) of 96% sodium hydroxide which was solid were portionwise added to the vessel at 50 degrees C. over 90 minutes. Then, the mixture was allowed to react at 50 degrees C. for 2 hours and, then, at 70 degrees C. for 2 hours. After the reaction, the excess epichlorohydrin was removed under a reduced pressure. In the vessel, 85 g of methylisobutylketone was added and the reaction product obtained was dissolved. 6.5 Grams (0.04 mol) of an aqueous 25% sodium hydroxide solution was added to the vessel and react at 70 degrees C. for 1 hour. After the reaction, the mixture was washed with water seven times, so that the aqueous phase was neutral. Methylisobutylketone was distilled off under heating and reduced pressure to obtain 67 g of epoxy compound 3 which was represented by the aforesaid formula (6) wherein R′, R² and R³ were H, the average of n was 1.2. An epoxy equivalent of epoxy compound 3 obtained was 176.

### Epoxy Compound 4

Biphenylaralkyl type epoxy resin: NC-3000, ex Nippon Kayaku Co., Ltd., in which the percentage of the number of the monovalent phenol is 100% and the percentage of the number of the divalent phenol is 0%, relative to the total number of the monovalent and divalent phenol groups, and the epoxy equivalent is 272.

### Epoxy Compound 5

Triphenyl alkane type epoxy resin: EPPN-501H, ex Nippon Kayaku Co., Ltd., in which the percentage of the number of the monovalent phenol is 100% and the percentage of the number of the divalent phenol is 0%, relative to the total number of the monovalent and divalent phenol groups and the epoxy equivalent is 165.

### [Component B]

Copolymer Obtained by Reacting an Alkenyl Group-Containing Epoxy Compound and an Organopolysiloxane

In a one-little, four-neck flask equipped with a reflux condenser, a thermometer, a stirrer and a dropping funnel, added were 200 g of a phenol novolac resin modified with allyl glycidyl ether, which had a phenol equivalent of 125 and an allyl equivalent of 1100, 80 g of chloromethyloxysilane and 0.6 g of cetyltrimethylammonium bromide, heated and stirred at 110 degrees C. for 3 hours. Then, the mixture was cooled to 70 degrees C. The pressure was reduced to 160 mmHg and, then, 128 g of an aqueous 50% sodium hydroxide solution was added dropwise to the mixture, while azeotropically removing water. The solvent was removed from the mixture under a reduced pressure. Subsequently, the residue was dissolved in a mixture of 300 g of methylisobutylketone and 300 g of acetone and, then, washed with water. The solvent was removed under a reduced pressure to obtain an allyl group-containing epoxy resin having an allyl equivalent of 1590 and an epoxy equivalent of 190. To the epoxy resin obtained, added were 170 g of methyl isobutyl ketone, 330 g of toluene and 0.07 g of an aqueous 2-ethylhexanol modified chloro platinic acid solution containing 2% of platinum. The mixture was subjected to azeotropic dehydration for 1 hour. Then, 133 g of an organopolysiloxane represented by the following formula (7) was added dropwise over 30 minutes at a reflux temperature and reacted at the same temperature with stirring for 4 hours. The product obtained was washed with water and the solvent was removed under a reduced pressure to obtain a pale yellow, non-transparent, solid copolymer. The epoxy equivalent was 280, the ICI melt viscosity at 150 degrees C. was 800 cP and the content of silicon was 31%.

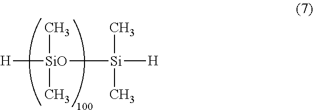

### [Component C]

### Phenol Compound 1

The compound represented by the following formula (8): SH-005-02, ex Meiwa Plastic Industries Ltd.

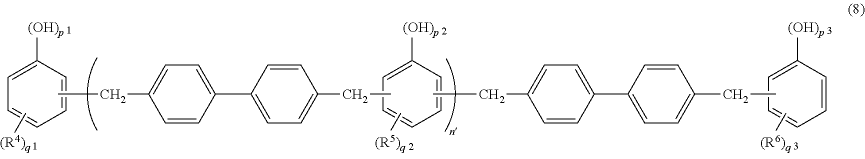

wherein R⁴, R⁵ and R⁶ are a hydrogen atom, the percentage of the number of the monovalent phenol is 36% and the percentage of the number of the divalent phenol is 64%, relative to the total number of the monovalent and divalent phenol groups, the average of n′ is 1.4, and the hydroxyl equivalent is 135.

### Phenol Compound 2

SH-005-04, ex Meiwa Plastic Industries Ltd.: the compound represented by the aforesaid formula (8) wherein R⁴, R⁵ and R⁶ are hydrogen atom, the percentage of the number of the monovalent phenol is 71% and the percentage of the number of the divalent phenol is 29%, relative to the total number of the monovalent and divalent phenol groups, and the hydroxyl equivalent is 169.

### Phenol Compound 3

MEHC-7851SS, ex Meiwa Plastic Industries Ltd.: the compound represented by the following formula (9) in which the percentage of the number of the monovalent phenol is 100% and the percentage of the number of the divalent phenol is 0%, relative to the total number of the monovalent and divalent phenol groups, and the hydroxyl equivalent is 203.

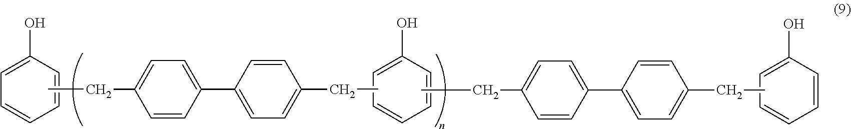

### Phenol Compound 4

TD-2131, ex DIC Corporation: the compound represented by the following formula (10) in which the percentage of the number of the monovalent phenol is 100% and the percentage of the number of the divalent phenol is 0%, relative to the total number of the monovalent and divalent phenol groups, and the hydroxyl equivalent is 110.

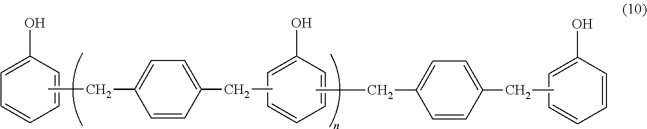

### [Component D]

Inorganic filler: fused spherical silica having a mean diameter of 15 micro meter, ex Tatsumori Ltd.

### [Component E]

Triphenylphosphine, TPP, trademark, ex Hokko Chemical Industry Co., Ltd.

Tetraphenylphosphonium Tetraphenylborate, TPP-K, trademark, ex Hokko Chemical Industry Co., Ltd.

### [Component F]

Phenol resin salt of 1,8-diazabicyclo[5.4.0]undecen-7-ene U-CAT(trademark) SA851, ex San-Apro Ltd.

Tetraphenylborate of 8-benzyl-1,8-diazabicyclo[5.4.0]undecen-7-ene, U-CAT(trademark) 5002, ex San-Apro Ltd.

### [Other Components]

### Releasing Agent:

Carnauba wax, TOWAX-131, ex Toakasei Co., Ltd.

### Silane Coupling Agent:

3-Mercaptopropyl trimethoxysilane, KBM-803, ex Shin-Etsu Chemical Co., Ltd.

### 3-Glycidyloxypropyltrimethoxysilane, KBM-403, ex Shin-Etsu Chemical Co., Ltd.

### Flame Retardant:

Molybdenum zinc oxide, KEMGARD-911B, ex Sherwin-Williams

### Ion Trapping Agent:

Hydrotalcite, DHT-4A-2, Kyowa Chemical Industry Co., Ltd.

The aforesaid components were melt-mixed homogeneously in the amounts described in the following Tables 1 and 2, with a heated two-roll kneader, cooled and, then, powdered to obtain compositions. The compositions obtained were evaluated according to the following manners. The results are as shown in Tables 3 and 4.

### (i) Spiral Flow

The spiral flow was determined in the conditions of 175 degrees C., 6.9 N/mm², and a molding time of 180 seconds, with a metallic mould according to the Epoxy Molding Materials Institute (EMMI) Standards.

### (ii) Glass Transition Temperature

The composition was transfer molded in the conditions of 175 degrees C., 120 seconds and 6.9 MPa and, then, post cured at 250 degrees C. for 4 hours to prepare a test piece having a size of 5×5×15 mm. The test piece was heated at a rate of temperature increase of 5° C./minute, while the size was measured with TMA 8310, ex Rigaku. An intersection of a tangent line of the curve between 50 degrees C. and 100 degrees C. and a tangent line of the curve between 270 degrees C. and 290 degrees C. was determined as a glass transition temperature (Tg).

(iii) Change in Weight During Storage at a High Temperature

The composition was transfer molded in the conditions of 175 degrees C., 120 seconds and 6.9 MPa and, then, post cured at 180 degrees C. for 4 hours to prepare a test piece having a width of 10 mm, a length of 100 mm and a thickness of 4 mm. The test piece was stored in an oven of 250 degrees C. for 336 hours. The weight of the test piece was measured before and after storage and the percentage of reduction was calculated.

### (iv) HTSL Property

A chip of 6 mm×6 mm, a die attach (DA) agent 84-1LMI-SR4, ex Ablestick, and a Quad Flat Package (QFP) lead frame which had 100 pins and was made of Cu alloy, Olin C7025, whose die pad part of 8 mm×8 mm and wire bonding parts were Ag-plated, were encapsulated with the composition in the conditions of 175 degrees C., 120 seconds and 6.9 MPa by transfer molding and post cured at 180 degrees C. for 4 hours. A tie bar was cut by a lead frame cutter to obtain QFP packages having a width of 20 mm, a length of 14 mm and a thickness of 2.7 mm. This package was stored in an oven of 200 degrees C. for 1000 hours. Any cracks on the package were observed. Any internal cracks were observed with an ultrasonic flaw detector. Any peeling from the lead frame was observed.

### (v) Heat Cycle Property

A chip of 6 mm×6 mm, a die attach (DA) agent 84-1LMI-SR4, ex Ablestick, and a Quad Flat Package (QFP) lead frame which had 100 pins and was made of Cu alloy, Olin C7025, whose die pad part of 8 mm×8 mm and wire bonding parts were Ag-plated, were encapsulated with the composition in the conditions of 175 degrees C., 120 seconds and 6.9 MPa by transfer molding and post cured at 180 degrees C. for 4 hours. A tie bar was cut by a lead frame cutter to obtain QFP packages having a width of 20 mm, a length of 14 mm and a thickness of 2.7 mm. The package was subjected to a heat cycle test where the package was left at −65 degrees C. for 30 minute and then 175 degrees C. for 30 minutes and this was repeated 1500 times. Any cracks on the package were observed. Any internal cracks were observed with an ultrasonic flaw detector. Any peeling from the lead frame was observed.

### (vi) Adhesiveness to a Cu Lead Frame

A QFP lead frame which had 100 pins wire, was made of Cu alloy (Olin C7025), and had a thickness of 0.15 mm, a width of 15 mm and a length of 15 mm, was encapsulated with the composition in the conditions of 175 degrees C., 120 seconds and 6.9 MPa by transfer molding to obtain a cured product having a base area of 10 mm² and a height of 3.5 mm on the lead frame. A shearing force was imposed on the device at a shearing rate of 0.2 mm/s with a die shear tester, ex DAGE. The shearing force at the time when the encapsulating material was peeled from the Cu lead frame (LF) was measured.

(vii) Moisture Absorption Reflow Test

A chip of 6 mm×6 mm, a die attach (DA) agent 84-1LMI-SR4, ex Ablestick, and a Quad Flat Package (QFP) lead frame which had 100 pins and was made of Cu alloy, Olin C7025, whose die pad part of 8 mm×8 mm and wire bonding parts were Ag-plated, were encapsulated with the composition in the conditions of 175 degrees C., 120 seconds and 6.9 MPa by transfer molding and post cured at 180 degrees C. for 4 hours. A tie bar was cut by a lead frame cutter to obtain QFP packages having a width of 20 mm, a length of 14 mm and a thickness of 2.7 mm. This package was allowed to absorb moisture in the conditions of 85 degrees C., 65% RH and 72 hours. The package was let to pass three times through an IR reflow furnace having a highest temperature of 265 degrees C. Any cracks on the package were observed. Any internal cracks were observed with an ultrasonic flaw detector. Any peeling from the lead frame was observed.

TABLE 1

| | | Example | | | | | | | | |
|---|---|---|---|---|---|---|---|---|---|---|
| Component, part by mass | | 1 | 2 | 3 | 4 | 5 | 6 | 7 | 8 | 9 |
| (A) | Epoxy compound 1 | 57.3 | 57.3 | 29.1 | 54.8 | | 57.0 | 59.0 | 41.3 | |
| | (36/64)* | | | | | | | | | |
| | Epoxy compound 2 | | | 29.1 | | 59.0 | | | | |
| | (71/29)* | | | | | | | | | |
| | Epoxy compound 3 | | | | | | | | | 50.9 |
| | (0/100)* | | | | | | | | | |
| (C) | Phenol compound 1 | 38.7 | 38.7 | 37.8 | 20.6 | 37.0 | 37.9 | 39.0 | 37.0 | 22.5 |
| | (36/64)* | | | | | | | | | |
| | Phenol compound 2 | | | | 20.6 | | | | | 22.5 |
| | (71/29)* | | | | | | | | | |
| (B) | Copolymer | 4.0 | 4.0 | 4.0 | 4.0 | 4.0 | 8.0 | 2.0 | 4.0 | 4.0 |
| (D) | Fused spherical | 420.0 | 420.0 | 420.0 | 420.0 | 420.0 | 420.0 | 420.0 | 420.0 | 420.0 |
| | silica | | | | | | | | | |
| | Biphenylaralkyl | | | | | | | | 17.7 | |
| | type epoxy resin | | | | | | | | | |
| | (100/0)* | | | | | | | | | |
| (E) | TPP | 0.8 | | 0.5 | | 0.6 | 0.8 | 0.8 | 0.8 | 0.8 |
| | TPP-K | | 1.0 | | 1.2 | | | | | |
| (F) | U-CAT SA851 | 0.5 | 0.8 | | | 0.6 | 0.5 | 0.5 | 0.5 | 0.5 |
| | U-CAT 5002 | | | 1.5 | 1.0 | | | | | |
| | Releasing agent | 1.5 | 1.5 | 1.5 | 1.5 | 1.5 | 1.5 | 1.5 | 1.5 | 1.5 |
| | 3-Mercaptopropyl | 0.5 | 0.5 | 0.5 | 0.5 | 0.5 | 0.5 | 0.5 | 0.5 | 0.5 |
| | trimethoxysilane | | | | | | | | | |
| | 3-Glycidyloxypropyl | 1.5 | 1.5 | 1.5 | 1.5 | 1.5 | 1.5 | 1.5 | 1.5 | 1.5 |
| | trimethoxysilane | | | | | | | | | |
| | Flame retardant | 5.0 | 5.0 | 5.0 | 5.0 | 5.0 | 5.0 | 5.0 | 5.0 | 5.0 |
| | Ion trapping agent | 1.5 | 1.5 | 1.5 | 1.5 | 1.5 | 1.5 | 1.5 | 1.5 | 1.5 |

*The parenthesized numerals are [percentage of the number of the monovalent phenol/percentage of the number of the divalent phenol].

TABLE 2

| | | Comparative Example | | | | | | | | |
|---|---|---|---|---|---|---|---|---|---|---|
| Component, part by mass | | 1 | 2 | 3 | 4 | 5 | 6 | 7 | 8 | 9 |
| (A) | Epoxy compound 1 (36/64)* | 57.3 | 57.3 | 57.3 | 57.3 | 60.6 | | | 47.5 | 66.0 |
| (C) | Phenol compound 1 (36/64)* | 38.7 | 38.7 | 38.7 | 38.7 | 39.4 | | | | |
| | Phenol compound 2 (71/29)* | | | | | | | | | |
| (B) | Copolymer | 4.0 | 4.0 | 4.0 | 4.0 | | | 4.0 | 4.0 | |
| (D) | Fused spherical silica | 420.0 | 420.0 | 420.0 | 420.0 | 420.0 | 420.0 | 420.0 | 420.0 | 420.0 |
| | Biphenylaralkyl type epoxy | | | | | | 57.3 | | | |
| | resin(100/0)* | | | | | | | | | |
| | Triphenyl alkane type epoxy | | | | | | | 57.0 | | |
| | resin(100/0)* | | | | | | | | | |
| | Biphenylaralkyl type phenol | | | | | | 42.7 | | 48.5 | |
| | resin(100/0)* | | | | | | | | | |
| | Phenol novolac resin | | | | | | | 39.0 | | 34.0 |
| (E) | TPP | 1.0 | | | | 1.0 | 1.0 | 1.0 | 1.0 | 1.0 |
| | TPP-K | | 1.2 | | | | | | | |
| (F) | U-CAT SA851 | | | 2.0 | | | | | | |
| | U-CAT 5002 | | | | 1.5 | | | | | |
| | Releasing agent | 1.5 | 1.5 | 1.5 | 1.5 | 1.5 | 1.5 | 1.5 | 1.5 | 1.5 |
| | 3-Mercaptopropyl | 0.5 | 0.5 | 0.5 | 0.5 | 0.5 | 0.5 | 0.5 | 0.5 | 0.5 |
| | trimethoxysilane | | | | | | | | | |
| | 3-Glycidyloxypropyl | 1.5 | 1.5 | 1.5 | 1.5 | 1.5 | 1.5 | 1.5 | 1.5 | 1.5 |
| | trimethoxysilane | | | | | | | | | |
| | Flame retardant | 5.0 | 5.0 | 5.0 | 5.0 | 5.0 | 5.0 | 5.0 | 5.0 | 5.0 |
| | Ion trapping agent | 1.5 | 1.5 | 1.5 | 1.5 | 1.5 | 1.5 | 1.5 | 1.5 | 1.5 |

*The parenthesized numerals are [percentage of the number of the monovalent phenol/percentage of the number of the divalent phenol].

TABLE 3

| | | Example | | | | | | | | |
|---|---|---|---|---|---|---|---|---|---|---|
| | | 1 | 2 | 3 | 4 | 5 | 6 | 7 | 8 | 9 |
| Spiral flow, inch | | 30 | 30 | 37 | 35 | 37 | 23 | 30 | 37 | 27 |
| Glass Transition Temperature, ° C. | | 187 | 183 | 178 | 177 | 172 | 182 | 190 | 183 | 202 |
| Percentage reduction (%) after storage | | 1.0 | 1.0 | 0.8 | 0.9 | 0.6 | 1.0 | 1.0 | 0.7 | 1.0 |
| at 250° C. for 336 h | | | | | | | | | | |
| HTSL test | The number of the | 0 | 0 | 0 | 0 | 0 | 0 | 0 | 0 | 0 |
| | packages where cracks | | | | | | | | | |
| | were confirmed** | | | | | | | | | |
| | The number of the | 0 | 0 | 0 | 0 | 0 | 0 | 0 | 0 | 0 |
| | package where peeling | | | | | | | | | |
| | from the lead frame was | | | | | | | | | |
| | confirmed** | | | | | | | | | |
| Heat cycle | The number of the | 0 | 0 | 0 | 0 | 0 | 0 | 0 | 0 | 0 |
| test | packages where cracks | | | | | | | | | |
| | were confirmed** | | | | | | | | | |
| | The number of the | 0 | 0 | 0 | 0 | 0 | 0 | 0 | 0 | 0 |
| | package where peeling | | | | | | | | | |
| | from the lead frame was | | | | | | | | | |
| | confirmed** | | | | | | | | | |
| Adhesiveness | Shearing force, MPa, | 12 | 14 | 11 | 12 | 13 | 12 | 11 | 13 | 11 |
| to a Cu lead | average on 8 packages | | | | | | | | | |
| frame | | | | | | | | | | |
| Moisture | The number of the | 0 | 0 | 0 | 0 | 0 | 0 | 0 | 0 | 0 |
| absorption | packages where cracks | | | | | | | | | |
| reflow test | were confirmed** | | | | | | | | | |
| | The number of the | 0 | 0 | 0 | 0 | 0 | 0 | 0 | 0 | 0 |
| | package where peeling | | | | | | | | | |
| | from the lead frame was | | | | | | | | | |
| | confirmed** | | | | | | | | | |

**12 packages were subjected to the HTSL test, the heat cycle test and the moisture absorption reflow test.

TABLE 4

| | | Comparative Example | | | | | | | | |
|---|---|---|---|---|---|---|---|---|---|---|
| | | 1 | 2 | 3 | 4 | 5 | 6 | 7 | 8 | 9 |
| Spiral flow, inch | | 30 | 30 | 22 | 34 | 30 | 50 | 45 | 40 | 40 |
| Glass Transition Temperature, ° C. | | 190 | 184 | 149 | 142 | 194 | 125 | 175 | 138 | 170 |
| Percentage reduction (%) after storage | | 1.0 | 1.0 | 1.0 | 1.0 | 1.0 | 0.6 | 1.6 | 0.7 | 1.3 |
| at 250° C. for 336 h | | | | | | | | | | |
| HTSL test | The number of the | 0 | 0 | 1 | 1 | 0 | 0 | 0 | 0 | 0 |
| | packages where cracks | | | | | | | | | |
| | were confirmed** | | | | | | | | | |
| | The number of the | 0 | 0 | 6 | 8 | 0 | 0 | 12 | 0 | 12 |
| | package where peeling | | | | | | | | | |
| | from the lead frame was | | | | | | | | | |
| | confirmed** | | | | | | | | | |
| Heat cycle | The number of the | 0 | 0 | 0 | 0 | 0 | 0 | 0 | 0 | 6 |
| test | packages where cracks | | | | | | | | | |
| | were confirmed** | | | | | | | | | |
| | The number of the | 3 | 6 | 4 | 2 | 12 | 0 | 8 | 0 | 6 |
| | package where peeling | | | | | | | | | |
| | from the lead frame was | | | | | | | | | |
| | confirmed** | | | | | | | | | |
| Adhesiveness | Shearing force, MPa, | 7 | 7 | 12 | 10 | 6 | 10 | 7 | 6 | 6 |
| to a Cu lead | average on 8 packages | | | | | | | | | |
| frame | | | | | | | | | | |
| Moisture | The number of the | 0 | 2 | 0 | 0 | 0 | 0 | 5 | 6 | 8 |
| absorption | packages where cracks | | | | | | | | | |
| reflow test | were confirmed** | | | | | | | | | |
| | The number of the | 4 | 6 | 0 | 0 | 0 | 0 | 7 | 0 | 4 |
| | package where peeling | | | | | | | | | |
| | from the lead frame was | | | | | | | | | |
| | confirmed** | | | | | | | | | |

**12 packages were subjected to the HTSL test, the heat cycle test and the moisture absorption reflow test.

The cured products from the compositions of Comparative Examples 1 and 2 which consisted of components (A) through (E) and lacked component (F), had the low adhesiveness to the Cu lead frame and the poor solder reflow property. The cured products from the compositions of Comparative Examples 3 and 4, which consisted of components (A) through (D) and (F) and lacked component (E), had the low glass transition temperatures and the poor heat resistances. In contrast, the cured products from the present compositions had the high glass transition temperatures and good heat resistances. Their thermal decomposition was small during the storage at the high temperature, and solder reflow property was good and the adhesiveness to the Cu lead frame was good.

### INDUSTRIAL APPLICABILITY

The present resin composition provides a cured product having a high glass transition temperature and good heat resistance. Therefore, thermal decomposition, e.g. reduction in weight, is small when the cured product is stored at a high temperature, particularly 200 to 250 degrees C. The cured product has low moisture absorption, good solder reflow property, and good adhesiveness to a Cu lead frame. The present composition has good moldability. Therefore, the present composition is suitable as a resin for encapsulating surface mounting type semiconductor devices.

1. A composition comprising the following components (A) to (F):
(A) an epoxy compound represented by the following general formula (1): 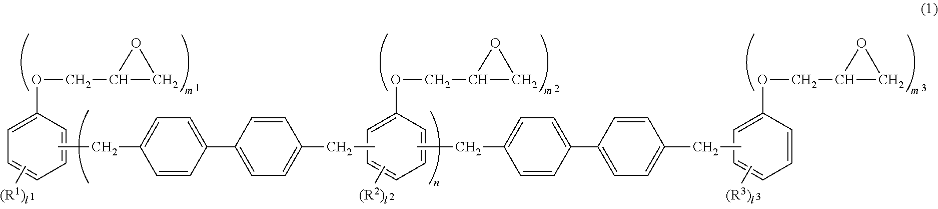
wherein R¹, R² and R³ are, independently of each other, a hydrogen atom or a substituted or unsubstituted, alkyl, aryl or aralkyl group having 1 to 10 carbon atoms, m¹, m², m³ are, independently of each other, an integer of 1 or 2, provided that a percentage of a total number of m¹, m² and m³ which are integer of 2 is 20 to 100%, relative to a total number of m¹, m² and m³, l¹ is 5 minus m¹, l³ is 5 minus m³, l² is 4 minus m²; and n is an integer of from 0 to 15,
(B) a copolymer obtained by a hydrosilylation between an alkenyl group-containing epoxy compound and an organopolysiloxane represented by the following average compositional formula (2), in an amount of 2 to 20 parts by mass, relative to total 100 parts by mass of components (A), (B) and (C),
$${H}_{a} {R}_{b} {SiO}_{\frac{4 \text{-} ( a + b )}{2}} \qquad ( 2 )$$
wherein R is, independently of each other, a substituted or unsubstituted, monovalent hydrocarbon group having 1 to 10 carbon atoms, a is a positive number of from 0.01 to 1, and b is a positive number of from 1 to 3, provided that a total value of a and b is from 1.01 to less than 4,
(C) a phenol compound represented by the following general formula (3), in an amount of 20 to 50 parts by mass, relative to total 100 parts by mass of components (A), (B) and (C), 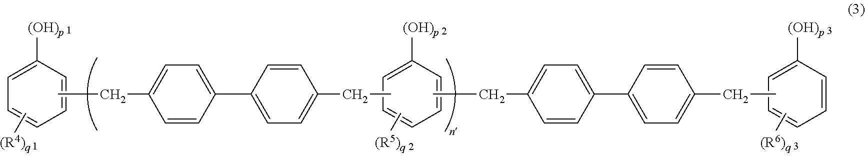
wherein R⁴, R⁵ and R⁶ are, independently of each other, a hydrogen atom or a substituted or unsubstituted, alkyl, aryl or aralkyl group having 1 to 10 carbon atoms, p¹, p² and p³ are, independently of each other, an integer of 1 or 2, provided that a percentage of a total number of p¹, p² and p³ which are an integer of 2 is 20 to 100%, relative to a total number of p¹, p² and p³, q¹ is 5 minus p¹, q³ is 5 minus p³, q² is 4 minus p²; and n′ is an integer of from 0 to 15,
(D) an inorganic filler in an amount of 150 to 1500 parts by mass, relative to total 100 parts by mass of components (A), (B) and (C),
(E) at least one compound selected from the group consisting of organic phosphines, tetra-substituted phosphonium tetraphenylborates and adducts of phosphines and quinones, in an amount of 0.1 to 5 parts by mass, relative to total 100 parts by mass of components (A), (B) and (C), and
(F) at least one selected from compounds represented by the following formula (I) and salts represented by the following formula (II), in an amount of 0.1 to 5 parts by mass, relative to total 100 parts by mass of components (A), (B) and (C), 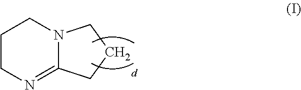
wherein d is an integer of from 1 to 3, 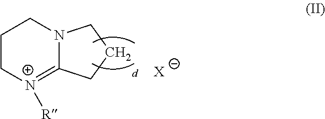
wherein R″ is a hydrogen atom, an aliphatic hydrocarbon group having 1 to 6 carbon atoms or an aromatic hydrocarbon group having 6 to 10 carbon atoms, d is an integer of from 1 to 3, and X is an anion selected from the group consisting of a tetraphenylborate ion, a phenol ion, a phenol resin ion, a toluene sulphonate ion, a halide ion and a carboxylate ion having 1 to 10 carbon atoms.

2. The composition according to claim 1, wherein the alkenyl group-containing epoxy compound in component (B) is at least one selected from the compounds having a moiety represented by the following average compositional formula (4) or (5): 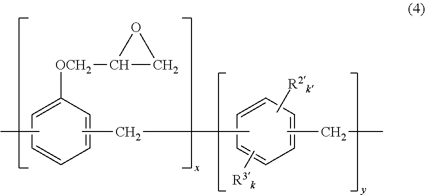
wherein R^{2′} is an alkenyl group-containing monovalent aliphatic hydrocarbon group which has 3 to 15 carbon atoms, R^{3′} is a glycidyloxy group or a group represented by —OCH₂CH(OH)CH₂OR′, wherein R is an alkenyl group-containing monovalent hydrocarbon group which has 3 to 10 carbon atoms, k is 1, k′ is 0 or 1, x is a positive number of 1 to 30, and y is a positive number of 1 to 3; 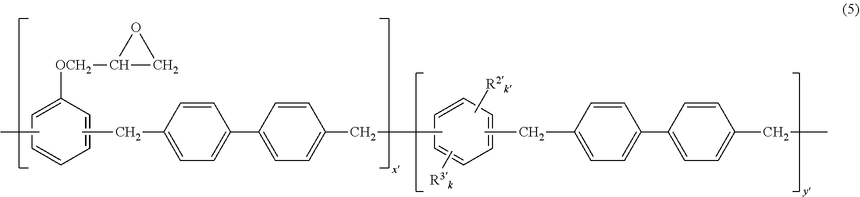
wherein R^{2′}, R^{3′}, k and k′ are as defined above, x′ is a positive number of 1 to 30, and y′ is a positive number of 1 to 3.

3. The composition according to claim 1 or 2, wherein the organopolysiloxane in component (B) is at least one selected from compounds represented by the following formula (a), (b) or (c): 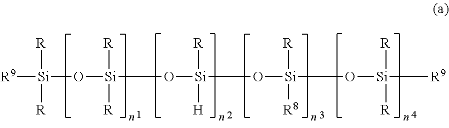
wherein R is, independently of each other, a substituted or unsubstituted, monovalent hydrocarbon group having 1 to 10 carbon atoms, R⁹ is a hydrogen atom or a group as defined for R, and R⁸ is a group represented by the following formula: 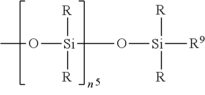
wherein R and R⁹ are as defined above, n⁵ is an integer of from 1 to 10,
n¹ is an integer of from 5 to 200, n² is an integer of from 0 to 2, n³ is an integer of from 0 to 10, and n⁴ is 1 or 0, wherein the parenthesized siloxane units may bond randomly or form a block unit, provided that the compound represented by the formula (a) has at least one hydrogen atom bonded to a silicon atom; 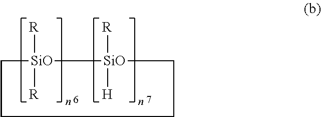
wherein R is as defined above, n⁶ is an integer of from 1 to 10, n⁷ is 1 or 2, an order of the parenthesized siloxane units is not limited; 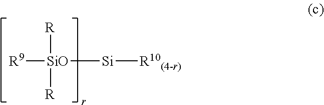
wherein R and R⁹ are as defined above, r is an integer of from 0 to 3, and R¹⁹ is a hydrogen atom or a monovalent hydrocarbon group which has 1 to 10 carbon atoms and may have an oxygen atom, wherein the compound represented by the formula (c) has at least one hydrogen atom bonded to a silicon atom.

4. A semiconductor device provided with a cured product obtained by curing the composition according to claim 1.
